(19) United States
(12) Patent Application Publication
(10) Pub. No.: US 2026/0171982 A1
(43) Pub. Date: Jun. 18, 2026

(54) RF AMPLIFIER AND RF RECEIVER HAVING THE SAME

(71) Applicant: ELECTRONICS AND TELECOMMUNICATIONS RESEARCH INSTITUTE, Daejeon (KR)

(72) Inventors: Sunwoo KONG, Daejeon (KR); Bong Hyuk PARK, Daejeon (KR); Seung Hun WANG, Daejeon (KR); Hui Dong LEE, Daejeon (KR)

(73) Assignee: ELECTRONICS AND TELECOMMUNICATIONS RESEARCH INSTITUTE, Daejeon (KR)

(21) Appl. No.: 19/411,785

(22) Filed: Dec. 8, 2025

(30) Foreign Application Priority Data
Dec. 12, 2024 (KR) 10-2024-0184894
Jun. 20, 2025 (KR) 10-2025-0081449

(51) Int. Cl. H03F 1/56; H03F 3/45; H04B 1/10; H04B 1/16

(52) U.S. Cl. CPC H03F 1/565; H03F 3/45179; H03F 3/45278; H03F 3/45475; H04B 1/10; H04B 1/1607; H03F 2200/222; H03F 2200/451

(57) ABSTRACT

An RF amplifier includes a transistor, a first inductance element, a second inductance element, and a third inductance element. The transistor includes an output terminal, a reference terminal, and a control terminal for receiving an input signal. The first inductance element is connected between the reference terminal of the transistor and a second power supply. The second inductance element is negatively coupled with the first inductance element and connected between the output terminal and a first power supply. The third inductance element is positively coupled with one of the first inductance element and the second inductance element and negatively coupled with the other.

### CROSS-REFERENCE TO RELATED APPLICATION

The present application claims the benefit of priority under 35 U.S.C. § 119 based on Korean Patent Application No. 10-2024-0184894 filed on Dec. 12, 2024 and Korean Patent Application No. 10-2025-0081449 filed on Jun. 20, 2025, with the Korean Intellectual Property Office, the entire content of which is incorporated herein by reference.

### BACKGROUND

### 1. Technical Field

The present disclosure relates to an RF amplifier and an RF receiver having the RF amplifier, and more particularly, to an RF amplifier used in a wireless communication system and an RF receiver having the RF amplifier.

### 2. Description of the Related Art

In a wireless communication system, an RF amplifier for effectively amplifying a high-frequency (RF) signal during a transmission and reception process of a signal is widely used. Generally, the RF amplifier is implemented in various structures such as a low noise amplifier (LNA), a power amplifier (PA), or a gain block, and is used to improve a signal-to-noise ratio (SNR) or to secure output power of a transmission signal.

A conventional RF amplifier adopts a common source structure or a common emitter structure based on a transistor (MOSFET or BJT), and adjusts frequency characteristics and impedance matching through an input matching network and an output matching network.

In order to improve noise performance of the low noise amplifier, it is advantageous to design a first stage as a single-ended stage and to apply a function of a balun between the first stage and a second stage. According to the Friis equation, the closer to the side where a signal is input, the greater the contribution to noise performance, so the number of active elements including a noise source in the first stage is reduced. A differential structure necessarily requires an even number of MOS transistors, and a single-ended structure requires an odd number of MOS transistors, so the latter is more advantageous in terms of noise performance.

### SUMMARY

An object of the present disclosure for solving the above-described problems is to provide a low-noise RF amplifier having high stability.

Another object of the present disclosure for solving the above-described problems is to provide an RF receiver including such an RF amplifier.

An RF amplifier according to exemplary embodiments may a transistor, a first inductance element, a second inductance element and a third inductance element. The transistor may include an output terminal, a reference terminal, and a control terminal for receiving an input signal. The first inductance element may be connected between the reference terminal and a second power supply. The second inductance element may be negatively coupled with the first inductance element and connected between the output terminal and a first power supply. The third inductance element may be positively coupled with one of the first inductance element and the second inductance element and negatively coupled with another.

The transistor may be implemented as an N-type MOSFET, and the output terminal, the reference terminal, and the control terminal may correspond to a drain terminal, a source terminal, and a gate terminal, respectively.

The transistor may be implemented as an NPN-type BJT, and the output terminal, the reference terminal, and the control terminal may correspond to a collector terminal, an emitter terminal, and a base terminal, respectively.

The RF amplifier may further comprise a matching network, and the input signal may be received at the control terminal through the matching network.

The RF amplifier may further comprise a differential amplifier connected to both ends of the third inductance element and outputting an output signal.

The first inductance element, the second inductance element, and the third inductance element may be formed on a substrate.

The second inductance element may be formed outside the first inductance element, and the third inductance element may be formed outside the second inductance element.

The first inductance element, the second inductance element, and the third inductance element may be connected with each other through vias in at least a portion of a region on the substrate.

The first inductance element, the second inductance element, and the third inductance element may be formed on a first surface of the substrate.

At least one of the first inductance element, the second inductance element, and the third inductance element may be formed on a first surface of the substrate, and remaining one or ones are formed on a second surface opposite to the first surface.

An RF amplifier according to exemplary embodiments may comprise a first stage including a transistor having a source-degeneration structure and configured as a single-ended structure, and a second stage including a differential amplifier and coupled with the first stage.

The first stage may include a first inductance element connected to a reference terminal of the transistor and a second inductance element connected to an output terminal of the transistor.

The first inductance element and the second inductance element may be negatively coupled with each other.

The first stage and the second stage may be coupled through a balun.

The balun may be implemented through a third inductance element that is positively coupled with one of the first inductance element and the second inductance element and negatively coupled with the another.

The first stage may receive an input signal through a matching network connected to a control terminal of the transistor.

The transistor may be an N-type MOSFET or an NPN-type BJT.

An RF receiver according to exemplary embodiments may comprise an antenna, an RF amplifier connected to the antenna, a mixer connected to the RF amplifier, and a signal source connected to the mixer and generating a carrier signal. The RF amplifier may comprise a transistor including an output terminal, a reference terminal, and a control terminal for receiving an input signal, a first inductance element connected between the reference terminal and a second power supply, a second inductance element negatively coupled with the first inductance element and connected between the output terminal and a first power supply, and a third inductance element positively coupled with one of the first inductance element and the second inductance element and negatively coupled with the other.

According to the present disclosure, it is possible to solve a stability problem in a single-ended common source amplifier structure that improves low-noise performance in an upper-mid band.

### BRIEF DESCRIPTION OF THE DRAWINGS

In order that the disclosure may be well understood, there will now be described various forms thereof, given by way of example, reference being made to the accompanying drawings, in which:

FIG. 1 is a circuit diagram for explaining input matching of a common source structure.

FIG. 2 is a circuit diagram in which a feedback capacitance Cgd is further shown in the common source structure of FIG. 1.

FIG. 3 is a conceptual diagram illustrating an RF amplifier according to exemplary embodiments of the present disclosure.

FIG. 4 is a circuit diagram illustrating the RF amplifier according to exemplary embodiments of the present disclosure shown in FIG. 3.

FIG. 5 is a plan view illustrating in more detail exemplary embodiments of a transformer including a first inductance element to a third inductance element shown in FIG. 3.

FIG. 6 is a diagram illustrating an RF receiver according to exemplary embodiments of the present disclosure.

FIGS. 7 to 9 are circuit diagrams illustrating exemplary embodiments and comparative examples for explaining effects according to differences in coupling of the first to third inductance elements of FIG. 5.

The drawings described herein are for illustration purposes only and are not intended to limit the scope of the present disclosure in any way.

### DETAILED DESCRIPTION

For a clearer understanding of the features and advantages of the present disclosure, exemplary embodiments of the present disclosure will be described in detail with reference to the accompanied drawings. However, it should be understood that the present disclosure may be not be limited to particular embodiments disclosed herein but includes all modifications, equivalents, and alternatives falling within the spirit and scope of the present disclosure. In the drawings, similar or corresponding components may be designated by the same or similar reference numerals.

The terminologies including ordinals such as “first” and “second” or another identifiers such as “A” and “B” may be used to discriminate a component from the other ones but may not be intended to be limiting to a specific component. For example, a second component may be referred to as a first component and, similarly, a first component may also be referred to as a second component without departing from the scope of the present disclosure. As used herein, the term “and/or” may include a presence of one or more of the associated listed items and any and all combinations of the listed items.

When a component is referred to as being “connected” or “coupled” to another component, the component may be directly connected or coupled logically or physically to the other component or indirectly through an object therebetween. Contrarily, when a component is referred to as being “directly connected” or “directly coupled” to another component, it is to be understood that there is no intervening object between the components. Other words used to describe the relationship between elements should be interpreted in a similar fashion.

The terminologies may be used herein for the purpose of describing particular exemplary embodiments only and may not be intended to limit the present disclosure. The singular forms include plural referents as well unless the context clearly dictates otherwise. Also, the expressions “comprises” or “includes” may be used to refer a presence of a combination of stated features, numbers, processing steps, operations, elements, or components, but may not be intended to preclude a presence or addition of another feature, number, processing step, operation, element, or component.

Unless defined otherwise, all terms used herein, including technical or scientific terms, have the same meaning as commonly understood by those of ordinary skill in the art to which the present disclosure pertains. Terms such as those defined in a commonly used dictionary should be interpreted as having meanings consistent with their meanings in the context of related literatures and will not be interpreted as having ideal or excessively formal meanings unless explicitly defined in the present application.

Hereinafter, preferred exemplary embodiments according to the present disclosure will be described in detail with reference to the accompanying drawings.

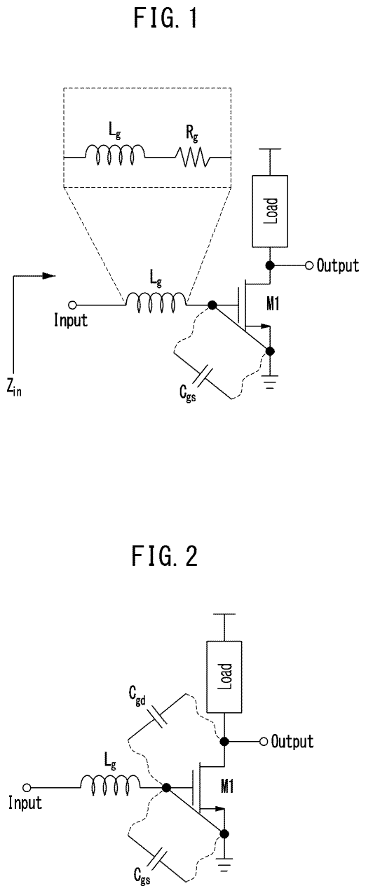

FIG. 1 is a circuit diagram for explaining input matching of a common source structure.

As shown in FIG. 1, among a common source structure, a common gate structure, and a cascode structure, the common source structure exhibits the best low-noise performance. This is because the common source structure can apply a series L-C configuration of an input matching circuit to obtain a Q-boosting effect, thereby having advantages of an improved noise figure and gain.

An input impedance Zin of the common source structure, as shown in FIG. 1, is expressed as in Equation 1 when a series L is used.

$${Z}_{i n} = \frac{1}{j ω {C}_{g s}} + j ω {L}_{g} + {R}_{g} \qquad [ Equation 1 ]$$

At this time, in order to remove a reactance component, the capacitance Cgs and the inductance Lg have a frequency at which resonance occurs, and the amplifier is matched at this frequency. The inductance Lg and the capacitance Cgs that determine the resonance frequency have a complementary relationship with each other. In an upper-mid band (7-15 GHz) that is generally referred to as such, the inductance Lg that causes the resonance frequency induces a sufficiently large series resistance Rg. When examining a noise-figure contribution component, the Rg noise component caused by the large Lg acts as a more significant factor than an influence by a MOS transistor. In order to solve this, the width of M1 may be increased to enlarge Cgs, and Lg may be set to a relatively small value.

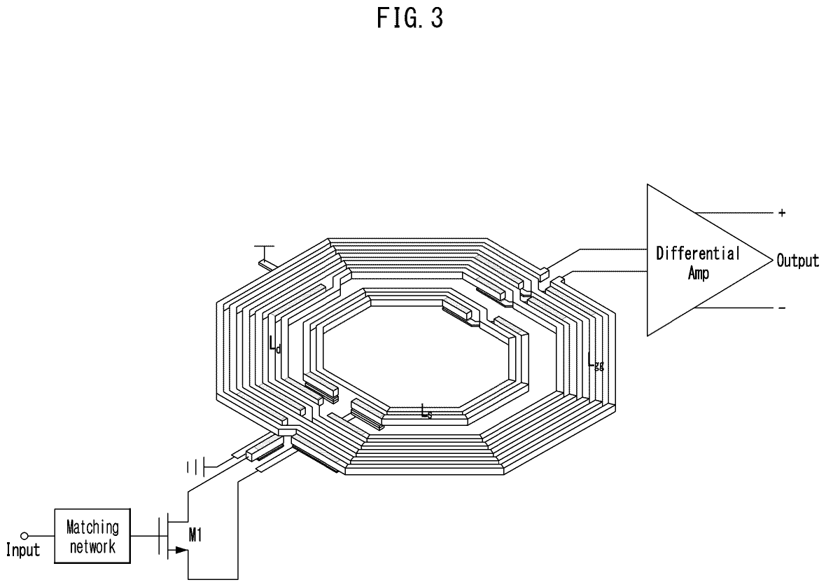

FIG. 2 is a circuit diagram in which a feedback capacitance Cgd is further shown in the common source structure of FIG. 1. As shown in FIG. 2, when the width of M1 is increased, the feedback capacitance Cgd also increases. Therefore, due to a Miller effect, the amplifier oscillates and a stability problem occurs. That is, since Cgd is located between a gate and a drain, an amplified effect by a voltage gain (Av) between an input (gate) and an output (drain) is obtained. Compared with this comparative example, exemplary embodiments of the present disclosure propose a method that uses negative feedback to increase stability while not reducing gain.

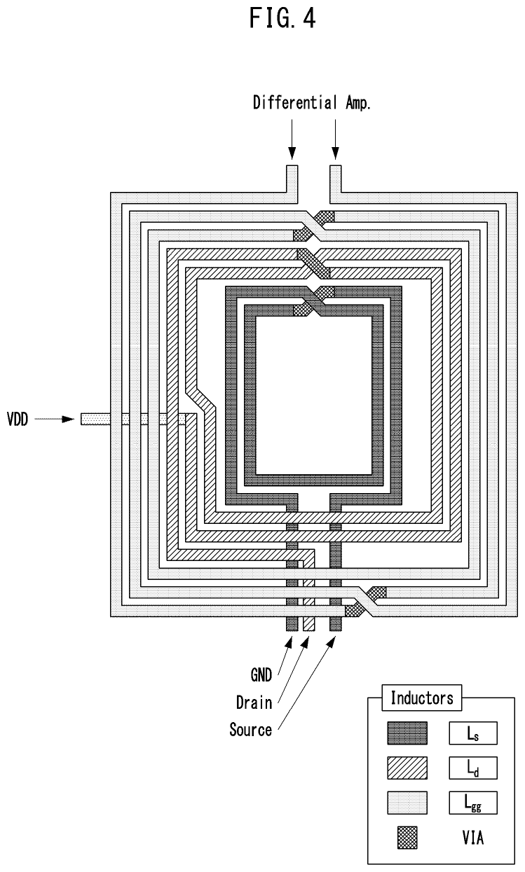

FIG. 3 is a conceptual diagram illustrating an RF amplifier according to exemplary embodiments of the present disclosure, and FIG. 4 is a circuit diagram illustrating the RF amplifier according to exemplary embodiments of the present disclosure shown in FIG. 3. Referring to FIGS. 3 and 4, the RF amplifier according to exemplary embodiments of the present disclosure includes a first stage and a second stage. The RF amplifier according to exemplary embodiments of the present disclosure further includes a matching network, and an input is received through the matching network and provided to a control terminal. The first stage includes a transistor (M1) having a source-degeneration structure. The transistor (M1) may be implemented as an N-type MOSFET or an NPN-type BJT. However, this is merely exemplary and not limited thereto. In addition, the first stage has a single-ended structure. As described above, when the structure is designed as a single-ended structure, it is advantageous in terms of noise performance. That is, since a differential structure necessarily requires an even number of transistors and a single-ended structure requires an odd number of transistors, the latter is advantageous for realizing low noise by reducing the number of active elements. The second stage includes a differential amplifier and is coupled with the first stage.

In the RF amplifier according to exemplary embodiments of the present disclosure, the first stage may include a first inductance element (Ls) and a second inductance element (Ld). The first inductance element (Ls) and the second inductance element (Ld) may be respectively connected to a reference terminal and an output terminal of the transistor (M1). In the RF amplifier according to exemplary embodiments of the present disclosure, the first inductance element (Ls) and the second inductance element (Ld) may be negatively coupled with each other. Such negative coupling is for negative feedback, which will be described in more detail later. In the RF amplifier according to exemplary embodiments of the present disclosure, the first stage and the second stage may be coupled through a balun. In the RF amplifier according to exemplary embodiments of the present disclosure, the balun may be implemented through a third inductance element (Lgg) coupled with the first inductance element (Ls) and the second inductance element (Ld). In the RF amplifier according to exemplary embodiments of the present disclosure, the first stage may receive an input through the matching network connected to the control terminal of the transistor (M1). The third inductance element (Lgg) is coupled with the first inductance element (Ls) and the second inductance element (Ld). The third inductance element (Lgg) connects the first stage that is single-ended to the differential amplifier, as a balun. The differential amplifier is resistant to common-mode noise and provides high stability due to a symmetrical structure.

From another perspective, the RF amplifier according to exemplary embodiments of the present disclosure includes the transistor (M1), the first inductance element (Ls), the second inductance element (Ld), and the third inductance element (Lgg). The RF amplifier according to exemplary embodiments of the present disclosure may further include a differential amplifier connected to both ends of the third inductance element (Lgg). The transistor (M1) includes a control terminal receiving an input signal, an output terminal, and a reference terminal. In the RF amplifier according to exemplary embodiments of the present disclosure, the transistor is implemented as an N-type MOSFET, and the control terminal, the output terminal, and the reference terminal respectively correspond to a gate terminal, a drain terminal, and a source terminal. Alternatively, the transistor may be implemented as an NPN-type BJT, and the output terminal, the reference terminal, and the control terminal respectively correspond to a collector terminal, an emitter terminal, and a base terminal.

The first inductance element (Ls) is connected between the reference terminal (or source terminal) of the transistor (M1) and a second power supply (for example, ground). Therefore, the transistor (M1) has a source-degeneration structure. The first inductance element (Ls) provides negative feedback to the transistor (M1). Due to such negative feedback, input impedance is increased, and gain of the circuit becomes less sensitive to process or temperature variations, thereby improving stability. More specifically, when a resistor or an inductor is connected to the reference terminal (or source terminal) of the transistor (M1), as drain current increases, source voltage also increases, thereby reducing gate-to-source voltage (Vgs), suppressing current increase, and thus providing negative feedback to the transistor (M1). That is, the transistor (M1) limits gain by itself and operates stably. In addition, as the input voltage becomes larger and more amplification occurs, distortion arises; however, the source-degeneration structure suppresses such distortion and thereby improves linearity of the output. Furthermore, in terms of an S-parameter, the first inductance element (Ls) improves S11. That is, in the source-degeneration structure, S11 becomes smaller, and reflection is reduced. Therefore, input reflection and oscillation are suppressed.

The second inductance element (Ld) is negatively coupled with the first inductance element (Ls) and connected between the output terminal and a first power supply. The second inductance element (Ld) connected to the reference terminal (for example, the source terminal) of the transistor (M1) provides negative feedback, and such negative feedback increases input impedance and makes circuit gain less sensitive to process or temperature variations, thereby improving stability. That is, when drain current flowing through the second inductance element (Ld) increases, a positive voltage is applied to a dot side of the first inductance element (Ls) negatively coupled with the second inductance element (Ld), thereby increasing voltage at the reference terminal (or source terminal) of the transistor (M1). As a result, the gate-to-source voltage (Vgs) decreases, suppressing current increase, and providing negative feedback to the transistor (M1). Furthermore, in terms of an S-parameter, the negatively coupled second inductance element (Ld) and first inductance element (Ls) are represented by S12 as feedback of a rear-stage signal to a front stage, and stability can be increased by adjusting the S12 value to be small.

The third inductance element (Lgg) is positively coupled with one of the first inductance element (Ls) and the second inductance element (Ld) and negatively coupled with the other. That is, when the third inductance element (Lgg) is positively coupled with the first inductance element (Ls), it is negatively coupled with the second inductance element (Ld). Conversely, when the third inductance element (Lgg) is negatively coupled with the first inductance element (Ls), it is positively coupled with the second inductance element (Ld). As described above, the third inductance element (Lgg) functions as a balun, suppresses oscillation at a high frequency, and flattens frequency characteristics of gain.

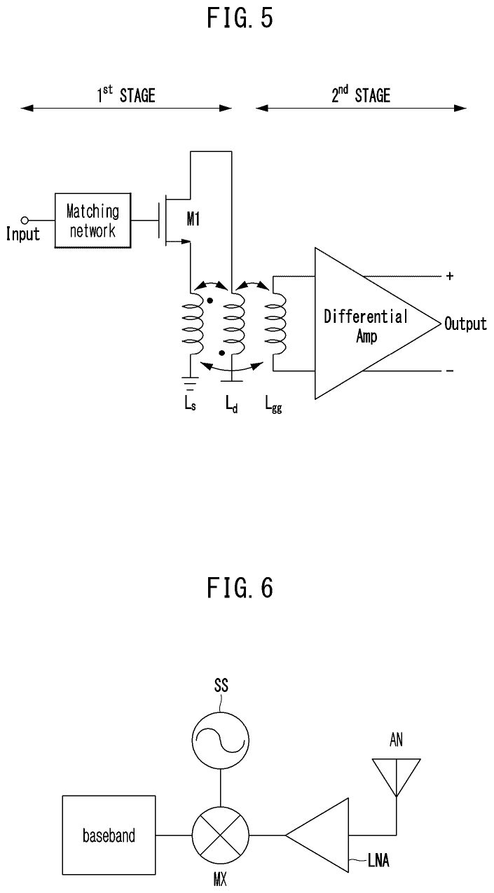

FIG. 5 is a plan view illustrating in more detail exemplary embodiments of a transformer including a first inductance element to a third inductance element shown in FIG. 3. The outer shapes of the first to third inductance elements shown in FIG. 3 are octagonal, and the outer shapes of the first to third inductance elements shown in FIG. 5 are rectangular; however, this is merely exemplary, and the outer shapes of the first to third inductance elements may have arbitrary shapes. As shown in FIG. 5, in the RF amplifier according to exemplary embodiments of the present disclosure, the first inductance element (Ls), the second inductance element (Ld), and the third inductance element (Lgg) may be formed on a substrate (not shown). For example, the substrate may be a rigid substrate or a flexible film. The first inductance element (Ls) and the second inductance element (Ld) may be formed by adhering a metal thin film to the substrate and patterning the metal thin film. In one example, the second inductance element (Ld) is formed outside the first inductance element (Ls), and the third inductance element (Lgg) may be formed outside the second inductance element (Ld).

In the RF amplifier according to exemplary embodiments of the present disclosure, the first inductance element (Ls), the second inductance element (Ld), and the third inductance element (Lgg) may be connected with each other through vias in at least a portion of a region on the substrate. More specifically, the first inductance element (Ls), the second inductance element (Ld), and the third inductance element (Lgg) are formed on the substrate in a state where they are cut so as to be configured as inductance elements, and an insulating film is formed on an upper portion thereof. The vias penetrate the insulating film to expose the first inductance element (Ls), the second inductance element (Ld), and the third inductance element (Lgg), and may connect each of the cut first inductance element (Ls), the second inductance element (Ld), and the third inductance element (Lgg).

Meanwhile, in the RF amplifier according to exemplary embodiments of the present disclosure, the first inductance element (Ls), the second inductance element (Ld), and the third inductance element (Lgg) may be formed on a first surface of the substrate. Alternatively, in the RF amplifier according to exemplary embodiments of the present disclosure, at least one of the first inductance element (Ls), the second inductance element (Ld), and the third inductance element (Lgg) may be formed on the first surface of the substrate, and the remaining one or ones may be formed on a second surface opposite to the first surface.

FIG. 6 is a diagram illustrating an RF receiver according to exemplary embodiments of the present disclosure. As disclosed in FIG. 6, the RF receiver includes an antenna (AN), an RF amplifier (LNA), a mixer (MX), and a signal source (SS) generating a carrier signal. The RF receiver may further include a baseband. The antenna (AN) receives an external RF signal. The RF amplifier (LNA) is connected to the antenna (AN). At this time, since the RF amplifier has been described above, a redundant description thereof will be omitted. The mixer (MX) is connected to the RF amplifier (LNA). In addition, the mixer (MX) is connected to the RF amplifier (LNA) and the signal source (SS). The mixer (MX) multiplies an output signal of the RF amplifier (LNA) by a carrier signal generated by the signal source (SS) to extract a signal. The baseband may perform functions such as digital modulation (e.g., QAM, PSK), FEC encoding/decoding, filtering, and the like.

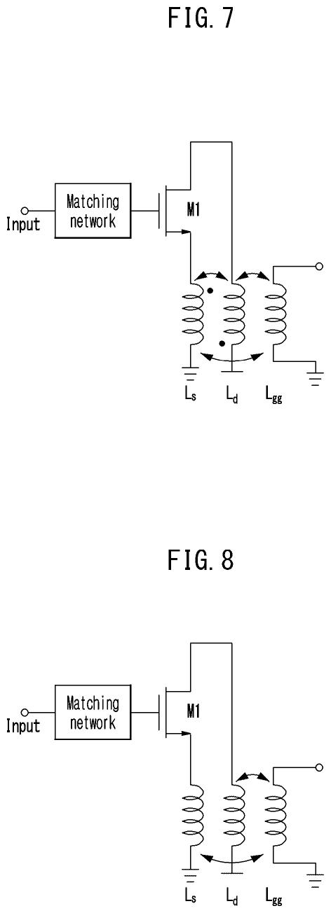

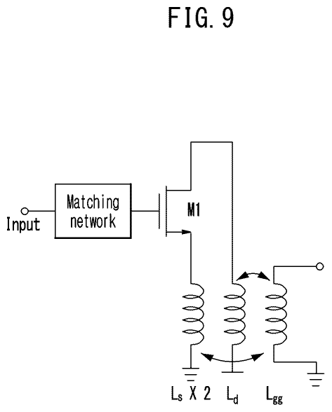

FIGS. 7 to 9 are circuit diagrams illustrating exemplary embodiments and comparative examples for explaining effects according to differences in coupling of the first to third inductance elements of FIG. 5. First, FIG. 7 illustrates an exemplary embodiment corresponding to exemplary embodiments of the present disclosure. FIG. 8 illustrates a comparative example in which coupling between the first inductance element (Ls) and the second inductance element (Ld) is removed, and a size of the first inductance element (Ls) is configured to be the same as that of FIG. 7. FIG. 9 illustrates another comparative example in which coupling between the first inductance element (Ls) and the second inductance element (Ld) is removed, and a size of the first inductance element (Ls) is increased to twice the size of the first inductance element (Ls) shown in FIG. 7. In all three cases, the same current is consumed, and all have similar noise figures. Table 1 below shows stability (μ), gain, and noise figure (NF) of the examples illustrated in FIGS. 7, 8, and 9.

TABLE 1

| | Stability (μ) | gain | NF |
|---|---|---|---|
| Embodiment of FIG. 6 | ++ | + | + |
| Comparative example of FIG. 7 | −(Oscillates) | + | + |
| Comparative example of FIG. 8 | + | − | + |

The exemplary embodiment of the present disclosure shown in FIG. 7 exhibits the highest stability while having a gain level similar to that of the comparative example of FIG. 8. However, the comparative example of FIG. 8 oscillates and thus has a stability problem. The embodiment of FIG. 9 does not oscillate but shows the lowest gain.

An operation of the method according to an embodiment of the present disclosure may be implemented as a program or code readable by a computer and recorded on a computer-readable recording medium. The computer-readable recording medium includes all types of recording devices in which information readable by a computer system is stored. In addition, the computer-readable recording medium may include computer-readable programs or codes stored and executed in a distributed manner in a computer system connected through a network.

The computer-readable recording medium may further include hardware devices specially configured to store and execute program instructions, such as a ROM, a RAM, or a flash memory. The program instructions may include not only machine code generated by a compiler but also high-level language code executable by a computer using an interpreter or the like.

Some aspects of the present disclosure have been described in the context of an apparatus, but this may also represent a description according to a corresponding method, where a block or device corresponds to a method step or a feature of a method step. Similarly, aspects described in the context of a method may also be represented as corresponding blocks, items, or features of a corresponding apparatus. Some or all of the method steps may be performed by, or using, hardware devices such as a microprocessor, a programmable computer, or an electronic circuit. In some embodiments, at least one of the most significant method steps may be performed by such a device.

In the embodiments, a programmable logic device (for example, a field-programmable gate array) may be used to perform part or all of the functions of the methods described herein. In the embodiments, the field-programmable gate array may operate together with a microprocessor for performing one of the methods described herein. In general, it is preferable that the methods are performed by a hardware device.

The description of the disclosure is merely exemplary in nature and, thus, variations that do not depart from the substance of the disclosure are intended to be within the scope of the disclosure. Such variations are not to be regarded as a departure from the spirit and scope of the disclosure. Thus, it will be understood by those of ordinary skill in the art that various changes in form and details may be made without departing from the spirit and scope as defined by the following claims.

What is claimed is:

1. An RF amplifier comprising:
a transistor including an output terminal, a reference terminal, and a control terminal for receiving an input signal;
a first inductance element connected between the reference terminal and a second power supply;
a second inductance element negatively coupled with the first inductance element and connected between the output terminal and a first power supply; and
a third inductance element positively coupled with one of the first inductance element and the second inductance element and negatively coupled with another.

2. The RF amplifier of claim 1, wherein the transistor is implemented as an N-type MOSFET, and
the output terminal, the reference terminal, and the control terminal correspond to a drain terminal, a source terminal, and a gate terminal, respectively.

3. The RF amplifier of claim 1, wherein the transistor is implemented as an NPN-type BJT, and
the output terminal, the reference terminal, and the control terminal correspond to a collector terminal, an emitter terminal, and a base terminal, respectively.

4. The RF amplifier of claim 1, further comprising a matching network, wherein the input signal is received at the control terminal through the matching network.

5. The RF amplifier of claim 1, further comprising a differential amplifier connected to both ends of the third inductance element and outputting an output signal.

6. The RF amplifier of claim 1, wherein the first inductance element, the second inductance element, and the third inductance element are formed on a substrate.

7. The RF amplifier of claim 6, wherein the second inductance element is formed outside the first inductance element, and the third inductance element is formed outside the second inductance element.

8. The RF amplifier of claim 7, wherein the first inductance element, the second inductance element, and the third inductance element are connected with each other through vias in at least a portion of a region on the substrate.

9. The RF amplifier of claim 6, wherein the first inductance element, the second inductance element, and the third inductance element are formed on a first surface of the substrate.

10. The RF amplifier of claim 6, wherein at least one of the first inductance element, the second inductance element, and the third inductance element is formed on a first surface of the substrate, and remaining one or ones are formed on a second surface opposite to the first surface.

11. An RF amplifier comprising:
a first stage including a transistor having a source-degeneration structure and configured as a single-ended structure; and
a second stage including a differential amplifier and coupled with the first stage.

12. The RF amplifier of claim 11, wherein the first stage includes a first inductance element connected to a reference terminal of the transistor and a second inductance element connected to an output terminal of the transistor.

13. The RF amplifier of claim 12, wherein the first inductance element and the second inductance element are negatively coupled with each other.

14. The RF amplifier of claim 12, wherein the first stage and the second stage are coupled through a balun.

15. The RF amplifier of claim 14, wherein the balun is implemented through a third inductance element that is positively coupled with one of the first inductance element and the second inductance element and negatively coupled with another.

16. The RF amplifier of claim 12, wherein the first stage receives an input signal through a matching network connected to a control terminal of the transistor.

17. The RF amplifier of claim 11, wherein the transistor is an N-type MOSFET or an NPN-type BJT.

18. An RF receiver comprising:
an antenna;
an RF amplifier connected to the antenna;
a mixer connected to the RF amplifier; and
a signal source connected to the mixer and generating a carrier signal,
wherein the RF amplifier comprises:
a transistor including an output terminal, a reference terminal, and a control terminal for receiving an input signal;
a first inductance element connected between the reference terminal and a second power supply;
a second inductance element negatively coupled with the first inductance element and connected between the output terminal and a first power supply; and
a third inductance element positively coupled with one of the first inductance element and the second inductance element and negatively coupled with the other.
